(19) United States
(12) Patent Application Publication
(10) Pub. No.: US 2007/0102033 A1
(43) Pub. Date: May 10, 2007

(54) DYNAMIC HEAT SINK FOR LIGHT EMITTING DIODES

(75) Inventor: Richard Joel Petrocy, Carteret, NJ (US)

Correspondence Address: STANLEY H. KREMEN, 4 LENAPE LANE, EAST BRUNSWICK, NJ, 08816, US

(73) Assignee: UNIVERSAL MEDIA SYSTEMS, INC., Warren, NJ (US)

(21) Appl. No.: 11/556,694

(22) Filed: Nov. 5, 2006

Related U.S. Application Data
(60) Provisional application No. 60/597,018, filed on Nov. 4, 2005.

(51) Int. Cl. H01L 35/28

(52) U.S. Cl. 136/203

(57) ABSTRACT

Dynamic heat sink that uses a thermoelectric cooler, such as a Peltier Junction, to move the heat at a LED junction to the other side of the cooling chip. This would allow the LED to run with more current in a much smaller area than a passive metal heat sink without burning out the junctions. The Present Invention would therefore permit a compact light device comprising a plurality of LED's to be constructed. Such a light device would be competitive with standard fluorescent bulbs by outputting light of equivalent brightness with less power dissipation.

### CROSS REFERENCE TO RELATED APPLICATIONS

This Present Application is the non-provisional counterpart of U.S. Provisional Patent Application Ser. No. 60/597,018 filed on Nov. 4, 2005, and claims the benefit of and priority to said provisional application, which is incorporated herein by reference in its entirety. This application is also related to U.S. Provisional Patent Application Ser. No. 60/596,809 filed on Oct. 21, 2005, and its non-provisional counterpart U.S. application Ser. No. 11/552,029 filed on Oct. 23, 2006, both of which are also incorporated herein by reference in their entirety.

### BACKGROUND OF THE INVENTION

A light emitting diode (LED) must be mounted on a relatively large metal heat sink to dissipate the heat when the diode is run using high current. It is desirable to run LED's using high current, because the higher the current, the higher the brightness of the emitted light. Furthermore, where a plurality of LED's are required for higher brightness, there are limits to how close they can be positioned next to one another due to the problem of heat dissipation.

A companion U.S. application Ser. No. 11/552,029 filed on Oct. 23, 2006, discloses an air-cooled high-efficiency LED spotlight or floodlight. The Present Invention differs from that disclosed in the companion application in that heat is borne away from the LED not by air cooled heat sink fins but rather by a thermoelectric cooler.

### DISCUSSION OF THE THERMOELECTRIC EFFECT

The thermoelectric effect is also known as the Peltier-Seebeck effect. The thermoelectric effect is the direct conversion of heat differentials to electric voltage and vice versa. This is closely related to the Thomson effect and to Joule heating. The Peltier-Seebeck and Thompson affects are reversible, while the Joule effect is not. The Peltier and Seebeck affects are the reversals of each other. The Seebeck effect is the conversion of temperature differences directly into electricity. Whenever there is a temperature difference between two different metals or semiconductors, a voltage is created that causes current to flow through conductors that form a complete circuit. The voltage created is of the order of several microvolts per degree difference (° K). The voltage can be derived from the formula:

$$V = {\int }_{{T}_{1}}^{{T}_{2}} ( {S}_{B} ( T ) - {S}_{A} ( T ) ) ⅆ T$$

where S_{A} and S_{B} are the Seebeck coefficients, and T₁ and T₂ are the temperatures of the two junctions. The Seebeck coefficients are non-linear. This Seebeck effect is the basic principle for the operation of thermocouples.

The Peltier effect is the reverse of the Seebeck effect. Whenever an electric voltage difference is applied to two dissimilar metals that form a junction, a temperature differential is created. The direction of heat transfer is determined by the polarity of the current. If the polarity is reversed, the direction of heat transfer is also reversed. A Peltier heater or cooler is known as a thermoelectric heat pump or as a thermoelectric cooler. This is a solid-state device that transfers heat from one side to the other.

The Thompson effect describes the condition where a current-carrying conductor having a temperature difference between two points on a conductor, will either absorb or emit heat, depending on the material. The amount of heat is derived from the equation:

$$q = ρ {J}^{2} - μ J \frac{ⅆ T}{ⅆ x}$$

where:
q is the heat generated per unit volume.
J is the current density.
ρ is the resistivity of the material
dT/dx is the temperature gradient along the wire.
μ is the Thomson coefficient.
The first term ρJ is simply the Joule heating, which is not reversible.
The second term, is the Thomson heat, which changes sign when J changes direction.

In metals such as zinc and copper, which have a hotter and at a higher potential in a cooler and at a lower potential, when current moves from a hotter end to the colder and, it is moving from a high to low potential, so there is an evolution of energy. This is called the positive Thompson effect. In metals such as cobalt, nickel, and iron, which have a cooler end at a higher potential and a hotter and at a lower potential, when current moves from the hotter end to the colder and, it is moving from a low to a high potential, there is an absorption of energy. This is called the negative Thompson effect. The Seebeck effect is actually a combination of the Peltier and Thompson effects.

The absolute temperature T, the Peltier coefficient Π, and the Seebeck coefficient S are related by the first Thompson relation:
S=Π×T.
These are related to the Thomson coefficient μ by the second Thompson relation:

$$μ = T \frac{ⅆ S}{ⅆ T}$$

Physical characteristics of the object to cool will determine what type of cold sink is best for an application. Some objects may require an extension of the module's cold surface called a cold shoe or cold plates. Copper and aluminum are good materials for fabricating cold side extensions and special interface shapes.

Thermoelectric heat pumps require clean DC power. Batteries, automotive and Marine DC systems, AC/DC converters, linear and switched DC power supplies are all appropriate sources. Voltage and current to the TE modules are rated for maximum voltage and current. Most applications are optimized at 75% of rated maximum. Reversing the polarity of power to the TE module will reverse the direction of pumped heat. Precise temperature control can be achieved with closed loop feedback systems regulating power to the module.

### SUMMARY OF THE INVENTION

The Present Invention is a dynamic heat sink that uses a thermoelectric cooler, such as a Peltier Junction, to move the heat at a LED junction to the other side of the cooling chip. This would allow the LED to run with more current in a much smaller area than a passive metal heat sink without burning out the junctions. The Present Invention would therefore permit a compact light device comprising a plurality of LED's to be constructed. Such a light device would be competitive with standard fluorescent bulbs by outputting light of equivalent brightness with less power dissipation.

### BRIEF DESCRIPTION OF THE DRAWINGS

FIG. 1 is an elevational view schematic of a light device containing eight LED's arranged in a cluster along with their dynamic heat sinks.

FIG. 2 is a plan view schematic showing the cluster of eight LED's of FIG. 1 mounted along with their dynamic heat sinks on a circular plate.

FIG. 3 is a schematic view of a single LED mounted on a heat sink comprising a Peltier Junction.

### DETAILED DESCRIPTION OF THE INVENTION

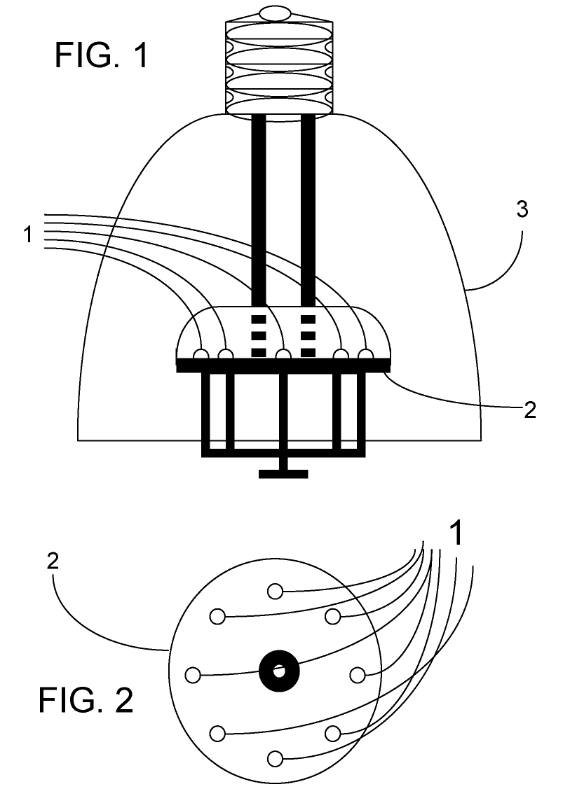

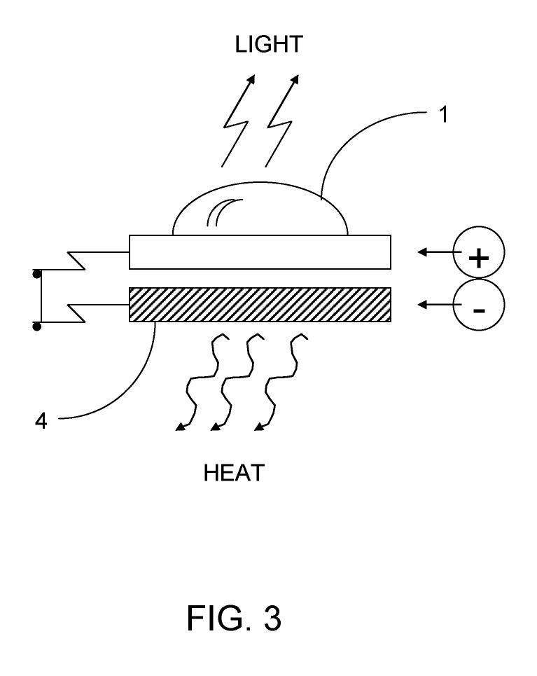

FIG. 1 is an elevational view schematic of a light device containing a plurality of LED's arranged in a cluster on a dynamic heat sink surface. In the figure, eight LED's, 1, are mounted with their heat sinks on plate 2. As previously discussed, copper and aluminum are excellent materials for fabrication of plate 2. LED's emit light which is reflected out of the device by reflector 3. Reflector 3 can have a simple paraboloid or ellipsoid shape with the focus in the center of the LED cluster plate. Alternatively, it can have a complex shape that would have multiple foci located at each LED position. A conventional or a Fresnel lens may also be placed at the output end of the lens to distribute the output light into a desired pattern. FIG. 2 is a plan view schematic showing the cluster of eight LED's of FIG. 1 mounted along with their dynamic heat sinks on circular plate 2.

FIG. 3 shows a single LED 1 mounted on the cold side of a heat sink 4 that constitutes the Present Invention. An LED normally generates heat during emission of light. A thermoelectric cooler, such as a Peltier Junction, removes the heat from the LED, and redirects it to emit from the hot side of the junction as shown.

I claim:

1. A light fixture device comprising electronic and non-electronic components, wherein said electronic components further comprise:
a) an electrically conductive connector adapted to allow electric current to flow through the electronic components:
b) at least one light emitting diode (LED); and,
c) a thermoelectric cooler configured such that when an electromotive force (EMF) is applied thereto, the cooler develops a hot side and a cold side;
wherein the at least one LED is attached to the cold side of the cooler in such a manner that the cooler acts as a heat sink that conducts away any heat generated by the LED.

2. The light fixture device of claim 1 wherein said at least one LED is a plurality of LED's.

3. The light fixture device of claim 2 wherein the non-electronic components comprise a thermally conductive mounting fixture to which both the cooler and the LED's are mounted.

4. The light fixture device of claim 3 wherein the plurality of LED's are mounted on the fixture in a cluster.

5. The light fixture device of claim 1 wherein the non-electronic components further comprise a reflective housing having an optically reflective inside surface, wherein light emitted from the at least one LED that impinges on said inside surface is redirected.

6. The light fixture device of claim 5 wherein the optically reflective inside surface is shaped so that the at least one LED is at a focal point of said inside surface, thereby permitting light emitted from the device to be collimated.

7. The light fixture device of claim 2 wherein the non-electronic components further comprise a reflective housing having an optically reflective inside surface, wherein light emitted from the plurality of LED's that impinges on said inside surface is redirected.

8. The light fixture device of claim 7 wherein the optically reflective inside surface is shaped so that the at least one LED of the plurality of LED's is at a focal point of said inside surface.

9. The light fixture device of claim 8 wherein the optically reflective inside surface is shaped so that more than one LED of the plurality of LED's is at a focal point of said inside surface.

10. The light fixture device of claim 8 wherein the optically reflective inside surface is shaped so that all of the LED's of the plurality of LED's is at a focal point of said inside surface.

11. The light fixture device of claim 1 wherein the non-electronic components comprise an output focusing device adapted to direct light emitted from the device into a desired output pattern.

12. The light fixture device of claim 11 wherein the output focusing device is a refractive lens.

13. The light fixture device of claim 11 wherein the output focusing device is a Fresnel lens.
